(19) United States
(12) Patent Application Publication
(10) Pub. No.: US 2011/0244683 A1
(43) Pub. Date: Oct. 6, 2011

(54) Fabricating Voids Using Slurry Protect Coat Before Chemical-Mechanical Polishing

(76) Inventor: Michiaki Sano, Aichi (JP)

(21) Appl. No.: 12/752,430

(22) Filed: Apr. 1, 2010

(51) Int. Cl. H01L 21/465; G03F 7/20; H01L 21/463

(52) U.S. Cl. 438/692; 430/311; 430/319; 257/E21.46; 257/E21.484; 257/E21.485

(57) ABSTRACT

A semiconductor structure is fabricated with a void such as a line, contact, via or zia. To prevent slurry particles from falling into and remaining in a void during a chemical-mechanical planarization process, a protective coat is provided in the void to trap the slurry particles and limit an extent to which they can enter the void. A metal layer is provided above the protective coat. Subsequently, the protective coat and trapped slurry particles are removed by cleaning, leaving a void which is substantially free of slurry particles. This is beneficial such as when the void is used as an alignment mark. The protective coat can be an organic layer such as spin-on carbon or i-line photoresist, an ashable material such as amorphous carbon, or a dissolvable and selective material such as SiN.

### BACKGROUND

The present technology relates to semiconductor fabrication technology.

Semiconductor structures are often fabricated with voids such as lines, contacts, vias or zias. A zia refers to a via which is etched through multiple levels of a 3-D device. For example, monolithic 3-D memory devices can include multiple levels of interconnected memory cells. Examples of monolithic 3-D memory devices can be found in U.S. 2005/0098800, titled “Nonvolatile memory cell comprising a reduced height vertical diode,” published May 12, 2005, and U.S. Pat. No. 6,952,030, titled “High-density three-dimensional memory cell”, issued Oct. 4, 2005, both of which are incorporated herein by reference. In such devices, the memory cells can be formed as diodes in polysilicon layers, while conductive rails which interconnect the memory cells can be formed by etching oxide layers and depositing a conductive material.

However, various challenges are encountered in forming interconnects between the layers of such memory devices and other 3-D integrated circuits, as well as in forming other voids in 2-D and 3-D devices. For example, etching of voids can be problematic when slurry particles are trapped in the void when a chemical-mechanical planarization (CMP) is performed.

### BRIEF DESCRIPTION OF THE DRAWINGS

FIG. 1 depicts a layered structure, including a patterned photoresist layer.

FIG. 2 depicts the layered structure of FIG. 1 after etching using the patterned photoresist layer to form a patterned semiconductor structure which includes at least one void.

FIG. 3 depicts the patterned semiconductor structure of FIG. 2 after removing the photoresist layer.

FIG. 4 depicts the patterned semiconductor structure of FIG. 3 after depositing an additional layer such as a metal.

FIG. 5 depicts the patterned semiconductor structure of FIG. 4 after depositing a protective coat.

FIG. 6 depicts the patterned semiconductor structure of FIG. 5 after performing chemical-mechanical polishing, where slurry particles are trapped by the protective coat in the void.

FIG. 7 depicts the patterned semiconductor structure of FIG. 6 after removing the trapped slurry particles and the protective coat in the void.

FIG. 8 depicts the patterned semiconductor structure of FIG. 7 after filling the void with metal and adding a top layer of metal.

FIG. 9 depicts a process for fabricating a semiconductor device.

FIG. 10 depicts further details of an example implementation of step 900 of FIG. 9.

FIG. 11 depicts a multi-level 3-D integrated circuit structure showing a trench and via interconnect.

FIG. 12 depicts a cross-sectional view of the multi-level 3-D integrated circuit structure of FIG. 11.

FIG. 13 depicts a memory cell in a 3-D memory device.

FIG. 14 depicts a process for forming a 3-D integrated circuit.

### DETAILED DESCRIPTION

A method is provided for fabricating a semiconductor device in which the formation of voids such as such as lines, contacts, zias or vias is improved. To prevent slurry particles from falling into and remaining in a void during a chemical-mechanical planarization process, a protective coat is provided in the void to trap the slurry particles and limit an extent to which they can enter the void. A metal layer is provided above the protective coat. Subsequently, the protective coat and trapped slurry particles are removed by cleaning, leaving a void which is substantially free of slurry particles. This is beneficial such as when the void is used as an alignment mark. The protective coat can be an organic layer such as spin-on carbon or i-line or g-line photoresist, an ashable material such as amorphous carbon, or a dissolvable and selective material such as SiN.

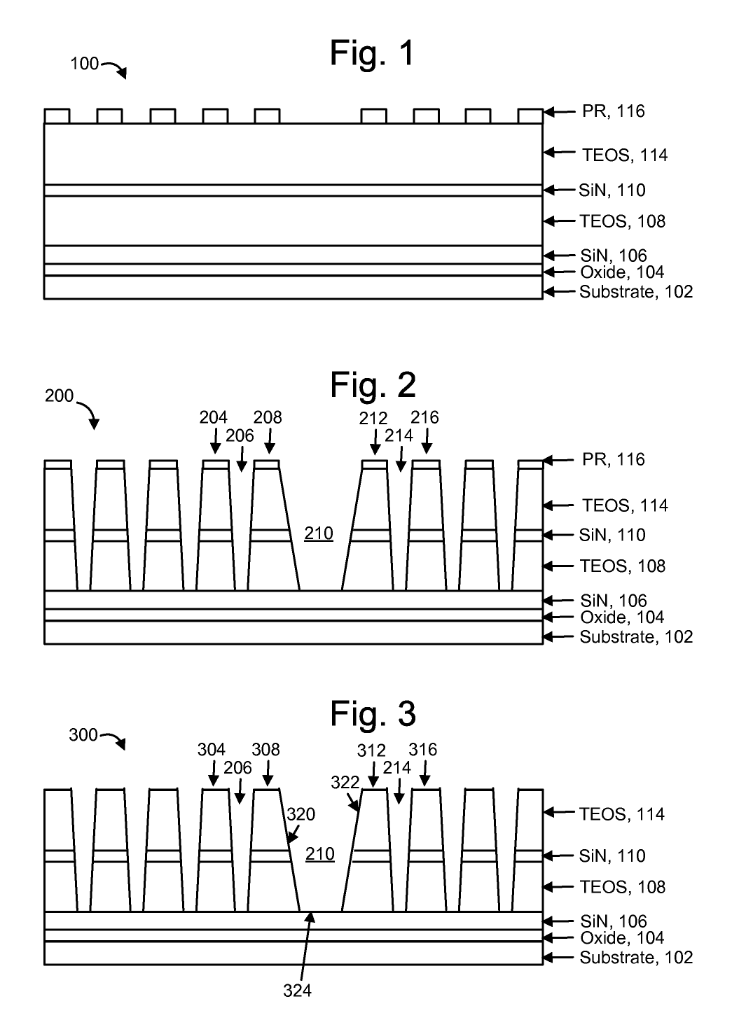

FIG. 1 depicts a layered structure 100, including a patterned photoresist (PR) layer 116. The layered structure 100 includes a substrate 102 such as a silicon substrate. The substrate can be any semiconducting substrate as known in the art, such as monocrystalline silicon, IV-IV compounds such as silicon-germanium or silicon-germanium-carbon, III-V compounds, II-VII compounds, epitaxial layers over such substrates, or any other semiconducting material. The substrate may include integrated circuits fabricated therein.

An oxide layer 104 is formed on the substrate. In some case, a reference to one layer being formed on another layer, or the like, as used herein may indicate that the one layer is in contact with the other layer, and that a bottom surface of the one layer is in contact with a top surface of the other layer. An example oxide layer is a zero level oxide having an example thickness of 10-100 nm. This can be a dummy layer or used to make a first layer alignment mark. A pad layer such as an SiN or metal layer 106 with an example thickness of 150 nm is formed on the oxide layer 104. The pad layer may provide a landing pad for a via, where the pad is a conductive connection point in a circuit.

A dielectric layer such as a first densified TetraEthyl OrthoSilane TEOS layer 108 having an example thickness of 400-800 nm after shrinkage is provided on the SiN or metal layer 106. In a 3-D monolithic memory device, one or more levels of memory cells may be formed in the TEOS layer 108, for instance, as discussed further below. Other types of insulating materials may be used as well, such as SiO₂ or other oxide, a high-dielectric film, Si—C—O—H film, or any other suitable insulating material. Polysilazane (PSZ), in the SiO₂ family, can be used as well. Note that the layered structure including the insulating layers may already have other components fabricated therein, such as memory cells, word lines and bit lines, when voids are formed.

A low-temperature water vapor generation (WVG) oxidation (oxidation by hydrogen combustion) may be carried out after the TEOS layer of film 108 is deposited. The oxidation can be performed at 250° C. for 30 minutes followed by 550° C. for 5 minutes. An SiN layer 110 is deposited on the TEOS layer 108. For instance, atomic layer deposition (ALD) at 500° C. to provide a thickness of 5 nm can be used. A second TEOS layer 114 can be provided on the SiN layer 110. The thickness can be the same or similar as the first TEOS layer 108. Similarly, in a 3-D monolithic memory device, one or more levels of memory cells may be formed in the second TEOS layer 114, for instance. An additional WVG oxidation can be then performed. Finally, a photoresist layer 116 can be provided on the second TEOS layer 114. The photoresist is shown after being patterned. In one possible approach, a pattern of a photomask is transferred to the photoresist layer 116 by selectively exposing the photoresist layer to UV light such as 193 nm (deep ultraviolet) light and removing the exposed portion of the photoresist using a developer.

Note that the figures are not necessarily to scale. Furthermore, where a cross-sectional view is shown, it will be appreciated that the structure extends depth wise as well, in three dimensions, such as to provide a planar area.

FIG. 2 depicts the layered structure of FIG. 1 after etching using the patterned photoresist layer 116 to form a patterned semiconductor structure 200, which includes at least one void 210. The etching can extend down to the SiN layer 106, so that a pattern is formed having a number of voids, such as voids 206, 210 and 214 and structures such as structures 204, 208, 212 and 216. The voids typically taper down with a decreasing thickness. The etching can include an S-MAP coat, PEP, RIE, ashing and a wet BHF wash with a 1.5 nm target. S-MAP refers to a stacked-mask process in a layered resist process. PEP refers to a polysilicon end point step process. RIE refers to reactive-ion etching, which uses chemically reactive plasma to remove material deposited on wafers. The plasma is generated under low pressure (vacuum) by an electromagnetic field. High-energy ions from the plasma attack the wafer surface and react with it. Ashing uses a plasma source to generate a monatomic reactive species which combines with the photoresist to form ash which is removed with a vacuum pump. Wet BHF (buffered hydrogen fluoride) washing is effective in removing oxides.

FIG. 3 depicts the patterned semiconductor structure of FIG. 2 after removing the photoresist layer. The resulting patterned semiconductor structure 300 includes a pattern having a number of voids, such as voids 206, 210 and 214 and structures such as structures 304, 308, 312 and 316. The void 210 includes side walls 320 and 322 and bottom surface 324.

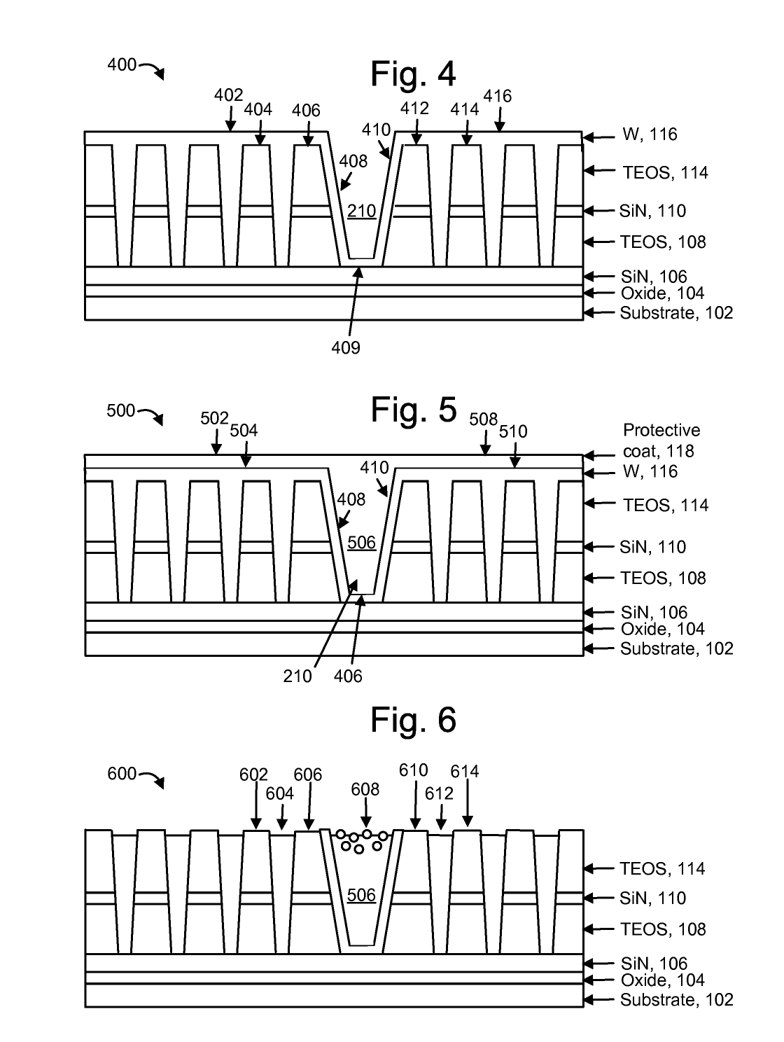

FIG. 4 depicts the patterned semiconductor structure of FIG. 3 after depositing an additional layer such as a metal. In the patterned semiconductor structure 400, the additional layer 116 can be a metal such as tungsten (W) or copper (Cu). The additional layer 116 includes portions 402 and 416 which are on top-facing surfaces of the TEOS layer 114, such as surfaces 404, 406, 412 and 414. Portions 408 and 410 of the additional layer coat the sidewalls of the void 210, while a portion 409 of the additional layer may also coat a bottom surface of the void 210. Optionally, a liner (not shown) is deposited before the additional layer 116. For example, a TiN liner with an example thickness of 5 nm may be used as a glue layer for a conductive material which is subsequently deposited, e.g., the additional layer 116.

FIG. 5 depicts the patterned semiconductor structure of FIG. 4 after depositing a protective coat. In the patterned semiconductor structure 500, portions 502 and 508 of a protective coat or material 118 are applied to the top-facing surfaces 504 and 510, respectively, of the additional layer 116, and a portion 506 of the protective coat 118 is applied in the void 210. The void may be substantially filled with the protective coat. The protective coat may have a viscosity similar to a liquid which allows it to flow into and fill up the void 210. The protective coat 118 serves to trap slurry particles from accumulating in the void 210 when a chemical-mechanical planarization (CMP) process is performed to planarize the additional layer 116.

CMP uses an abrasive and corrosive chemical slurry or colloid with a polishing pad and retaining ring. For example, Al₂O₃ or SiO₂ based abrasive slurry particles can be used. The slurry particles can have a grain size and adhesion which are specified based on the pattern size. The pad and wafer are pressed together by a dynamic polishing head and held in place while the dynamic polishing head is rotated. This removes material from the top surface of the wafer and tends to even out any irregular topography, preparing the wafer for the formation of additional circuit elements. However, the slurry particles can accumulate in a void.

An accumulation of slurry particles in a void can be problematic such as when the void is used as an alignment mark. Typically, a number of such voids in a layer can be used as alignment marks. For instance, an alignment mark can be used to align a following photomask or to check an alignment of the pattern in the semiconductor structure 500. In this situation, the slurry particles can render the alignment process more difficult or impossible since the void cannot be clearly detected. As a result, mis-alignment of a following layer in the semiconductor structure can occur. The problem of slurry particles being trapped in a void occurs when certain patterns and void widths are used, such as in an accessory pattern. For example, an alignment mark may be 500×2000 nm. In another example, a scanning electron microscope (SEM) bar or alignment mark can have a width of about 0.8-2 μm and a length of about 30 μm. These marks are voids (506) which have a certain size range which can be more susceptible to slurry accumulation. The top view of the void can be elliptical, circular, or elongated, for instance. As an example, a void having a top view area of about 100×200 nm to about 200×400 nm at a top of the void, and is less susceptible to slurry accumulation. A typical void depth is 800-1600 nm. For instance, a depth of 800 nm may be associated with a top view area of about 100×200 nm, and a depth of 1600 nm may be associated with a cross-sectional area of about 200×400 nm. A depth of the void can be at least about 800 nm.

During alignment, an alignment mark is used by scanning lithography. A scanner checks the mark and uses its location as feedback. Overlay boxes are used to measure how the layers differ from one another in their alignment. A via pattern can use an overlay box to measure a layer below and adjacent. Normally one layer has at least one alignment mark and two overlay box sets.

One potential way to minimize slurry accumulation is to provide a greater thickness for the portions 408 and 410 of the additional layer 116 which coat the sidewalls of the void 210. For instance, the portions 408 and 410 of the additional layer 116 could be so thick that they fill most of the void 210. However, if the thickness of the additional layer 116 such as W is too great, this can cause peeling between the W and the TEOS layers due to stress differences. Another potential approach, lithographic tuning, can result in dust and alignment errors. Tuning of the alignment mark design can also be problematic depending on the fabrication process. Different cleaning liquids and slurry materials could also be used. However, these approaches are also problematic and can lead to dishing. Modification of the k-process, e.g., the alignment mark lithography and etch process, generally is expensive since added lithography or etching is needed. In contrast, the use of a protective coat can successfully trap slurry particles so that they do not fall to the bottom of the void, and can be easily removed when the protective coat is subsequently removed after CMP. The technique is successful regardless of the thickness of the additional layer 116.

Various types of protective coats can be used. For example, the protective coat can be an organic or carbon-based layer. Examples include spin-on carbon and photoresist such as i-line or g-line photoresist, for which the developing light wavelength is the i-line or g-line of a Mercury-vapor lamp. i-line or g-line photoresist are organic. Spin-on carbon can be used in a liquid form, and can include i-line or g-line photoresist. A liquid can fill a wide void and be planarized. These examples are relatively inexpensive. An example thickness for an i-line or g-line photoresist coat is 1 μm. In a spin-on carbon process, organic polymer with high carbon content is spin-cast to form a carbon hard mask film. When the protective coat is a photoresist, a pre-CMP bake can be used to better cure the photoresist. For example, a temperature of 80 to 140° C. and a time of 40 to 90 seconds can be used. A pre-bake and/or bake of photoresist allows the photoresist to flow into the void.

In another approach, the protective coat can be an ashable material such as amorphous carbon, such as the product “Advanced Patterning Film (APF)®”, which is available from Applied Materials Inc., Santa Clara, Calif. An ashable material has many qualities of an organic material. In another approach, the protective coat can be a dissolvable and selective material such as SiN. SiN can be removed by H₃PO₄, which does not remove TEOS. When removing an organic layer, O₂ Plasma or O₃ treatment can be used. SiN does not need O₂ Plasma or O₃ treatment to be removed. So, SiN can be used in an oxygen-free process.

FIG. 6 depicts the patterned semiconductor structure of FIG. 5 after performing chemical-mechanical polishing, where slurry particles are trapped by the protective coat in the void. As mentioned, CMP uses a slurry in which particles or portions of the slurry can be left behind in a void after cleaning. The patterned semiconductor structure 600 includes regions which are voids filled with the additional layer 116, such as regions 604 and 612. Additionally, top-facing surfaces of the TEOS layer 114 are revealed, such as surfaces 602, 606, 610 and 614. The top-facing surfaces 602, 606, 610 and 614 are essentially the same as the top-facing surfaces 404, 406, 412 and 414, respectively, of FIG. 4. Portions of the top-facing surfaces of the additional layer 116 and of the TEOS layer 114 may be worn away by the CMP. Typically, the additional layer such as W will have a higher polishing rate than the TEOS so that the TEOS regions 602, 606, 610 and 614 are higher than the W regions after the CMP.

Portions of the slurry such as slurry particles 608 are trapped in the portion 506 of the protective coat 118, typically near a top region of the portion 506. The portion 506 of the protective coat 118 thus limits an extent to which the slurry particles can enter the void 210. If the portion 506 of the protective coat 118 was not present, the slurry particles can accumulate in the void 210, falling to the bottom of the void. Note that the portion 506 of the protective coat 118 can substantially fill the void 210 in one approach. Or, the protective coat 118 can fill only a fraction of the void 210, while still being effective in trapping and enabling subsequent removal of the slurry particles.

The CMP removes the portions 502 and 508 of the protective coat 118 which are on the top-facing surfaces 504 and 510, respectively, of the additional layer 116, outside and lateral to an area of the void 210/protective coat portion 506. The CMP also removes portions of the additional layer 116 which have the top-facing surfaces 402 and 410, and which are on the top-facing surfaces of the layer 114. As a result, the CMP essentially reveals the layer 114.

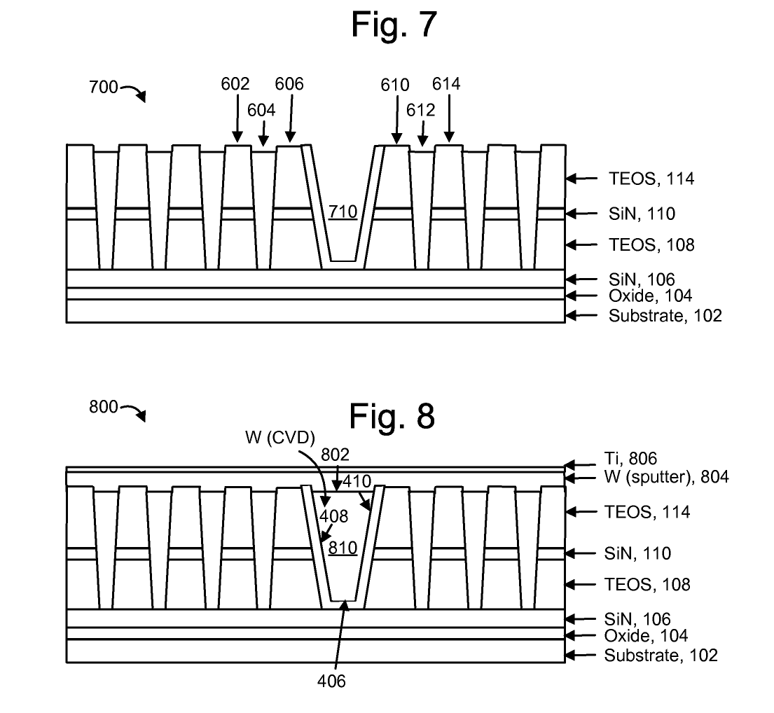

FIG. 7 depicts the patterned semiconductor structure of FIG. 6 after removing the trapped slurry particles and the protective coat in the void. In the patterned semiconductor structure 700, a void 710 corresponding to the void 210 of FIG. 2 is obtained after the trapped slurry particles 608 and the portion 506 of the protective coat are cleaned away using an ash/wet cleaning process. Advantageously, no lithography or etching is needed to remove the trapped slurry particles 608 and the portion 506 of the protective coat.

FIG. 8 depicts the patterned semiconductor structure of FIG. 7 after filling the void with metal and adding a top layer of metal. In the patterned semiconductor structure 800, a conductive filler 810 is provided in the void 710. For example, W may be deposited using chemical vapor deposition (CVD), which provides good coverage. The conductive filler 810 forms a continuous conductive path, e.g., through different levels of a 3-D monolithic memory device to provide a vertical conductive interconnect in the device.

A conductive material 804 is provided as a new top layer, including on a top-facing surface 802 of the filler 810 such as a metal which fills in the void. For example, the material 804 may be W which is provided by sputtering, such as to provide a low resistance control line, e.g., word line or bit line, in a memory device. An example thickness of the material 804 is 100-150 nm. A Ti layer 806, with an example thickness of 5 nm, may be provided on the material 804.

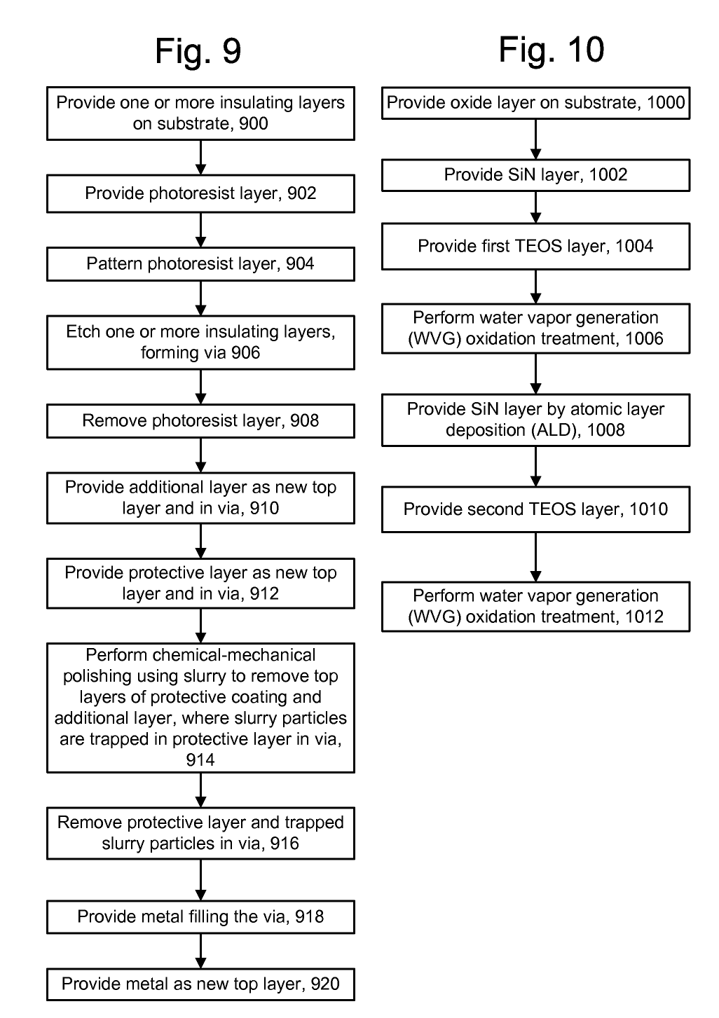

FIG. 9 depicts a process for fabricating a semiconductor device. Step 900 includes providing one or more insulating layers on a substrate. These can be layers in which memory cells are formed in a 3-D monolithic memory device for instance. However, other applications such as single-layer memory devices as well as any general semiconductor device are possible. Step 902 provides a photoresist layer (e.g., 116, FIG. 1) as a new top layer. Step 904 patterns the photoresist layer according to a desired pattern which is to be formed in the one or more insulating layers. Step 906 etches the one or more insulating layers, forming one or more vias (e.g., 210, FIG. 2). Step 908 removes remains of the photoresist layer. Step 910 provides an additional layer (e.g., 116, FIG. 4) as a new top layer and in the via. Step 912 provides a protective layer (e.g., 118, FIG. 5) as a new top layer and in the via. Step 914 performs chemical-mechanical polishing using a slurry to remove the top layers of the protective coat and the additional layers, where slurry particles are trapped in the protective layer in the via. Step 916 includes removing the protective layer and the trapped slurry particles, both from the via. Step 918 includes providing a metal (e.g., 810, FIG. 8) filling the via. Step 920 includes providing a metal (e.g., 804, FIG. 4) as a new top layer.

FIG. 10 depicts further details of an example implementation of step 900 of FIG. 9. The one or more insulating layers on a substrate can be provided according to the desired application. An example implementation provides multiple layers in which memory cells are formed in a 3-D monolithic memory device. Step 1000 provides an oxide layer (e.g., 104, FIG. 1) on the substrate. Step 1002 provides an SiN or metal layer (e.g., 106, FIG. 1). Step 1004 provides a first TEOS layer (e.g., 108, FIG. 1). This layer can include two levels of memory cells, for instance, such as resistive random access memory cells (ReRAMs). Step 1006 performs a WVG oxidation treatment. Step 1008 provides an SiN layer (e.g., 110, FIG. 1) by using ALD. Step 1010 provides a second TEOS layer (e.g., 114, FIG. 1). As before, this layer can include two levels of memory cells, for instance, such as resistive random access memory cells (ReRAMs). Step 1012 performs a WVG oxidation treatment.

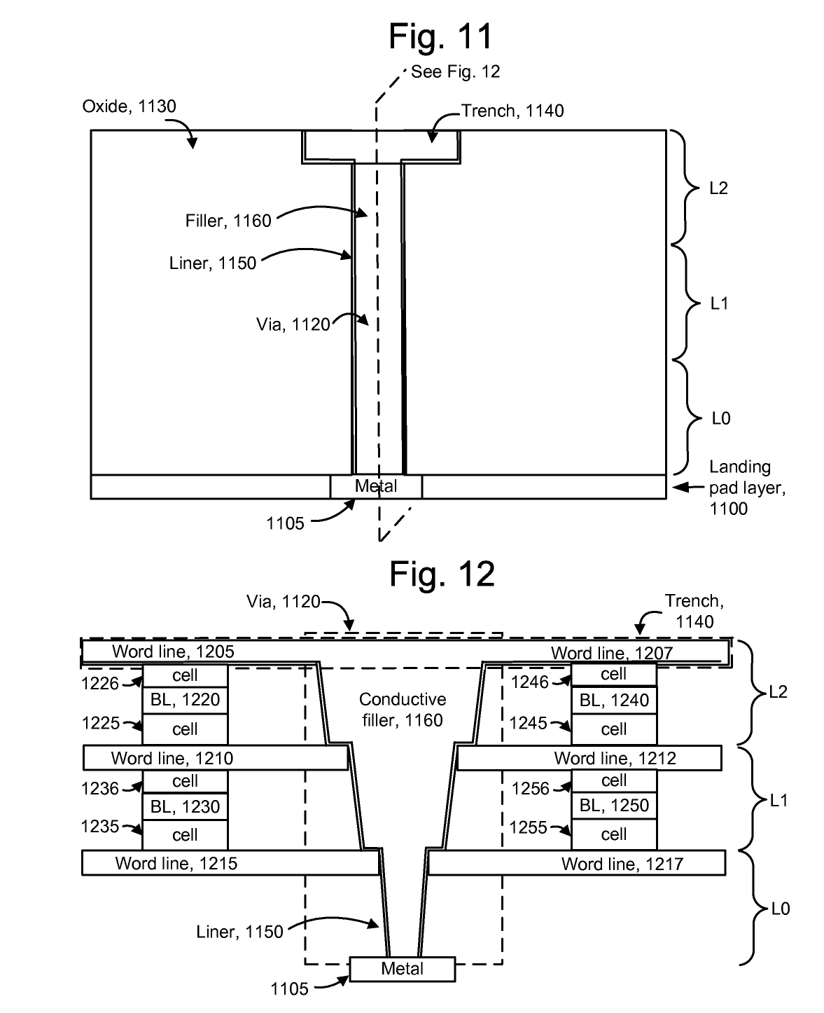

FIG. 11 depicts a multi-level 3-D integrated circuit structure showing a trench and via interconnect. A monolithic three dimensional memory array or device is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in U.S. Pat. No. 5,915,167 to Leedy, titled “Three dimensional structure memory,” incorporated herein by reference. The substrates may be thinned or removed from the memory levels before bonding, but as the memory levels are initially formed over separate substrates, such memories are not true monolithic three dimensional memory arrays. A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

In such 3-D applications, a via, also referred to as a zia, contacts multiple levels of a 3-D device simultaneously. See, for example, V. Dunton et al., “Zias: Vertical wires in 3-D memory devices,” Matrix Semiconductor, 2005 VMIC Conference, Oct. 4-6, 2005, incorporated herein by reference. The via can be etched through multiple levels of the device in a single pass through an etcher and may have a depth of, e.g., 800-1600 nm.

An example multi-level device includes three levels, L0, L1 and L2. An example via 1120, at its bottom, connects to a respective metal pad 1105 in a landing pad layer 1100. The trench 1140 at the top of the via 1120 extends laterally in one of the levels of the device, L2, to provide a word line, bit line or other routing line. The oxide 1130, liner 1150 and conductive filler 1160, are also depicted. Appropriate control circuits of the multi-level device are used to provide voltages to the via and trench via the metal pad 1105.

FIG. 12 depicts a cross-sectional view of the multi-level 3-D integrated circuit structure of FIG. 11. The cross-section depicts the metal pad 1105, via 1120, trench 1140, liner 1150, conductive filler 1160 and levels L0, L1 and L2 of FIG. 11. In particular, it can be seen that the via 1120 has a width which increases step wise with each higher level. Further, the via contacts, or lands on, word lines at each level of the device, in this example. A via could similarly contact bit lines at different levels of a device. At the top of the via, the trench 1140 is used to provide word lines 1205 and 1207. The via, which includes the liner 1150 and conductive filler 1160, lands on word lines 1210 and 1212 in the L1 level of the device, and on word lines 1215 and 1217 in the L0 level of the device. In this mirror image configuration, the word lines extend on both sides of the via 1120. In other configurations, the word lines may extend from only one side of the via 1120. For a memory device, the word lines are conductive rails which contact bottom portions of memory cells, such as example cells 1225, 1235, 1245 and 1255. Further, bit lines (BLs) can be formed as conductive rails which communicate with top portions of the memory cells, such as example bit lines 1220, 1230, 1240 and 1250 which communicate with cells. For example, bit line 1220 can communicate with cells 1225 and 1226, bit line 1230 can communicate with cells 1235 and 1236, bit line 1240 can communicate with cells 1245 and 1246, and bit line 1250 can communicate with cells 1255 and 1256. Word line 1205 communicates with cell 1226, word line 1210 communicates with cells 1225 and 1236, and word line 1215 communicates with cell 1235. Similarly, word line 1207 communicates with cell 1246, word line 1212 communicates with cells 1245 and 1256, and word line 1217 communicates with cell 1255. In this example, there are two cells arranged vertically in each of the layers L1 and L2. Further details regarding operation of the memory cells are discussed next.

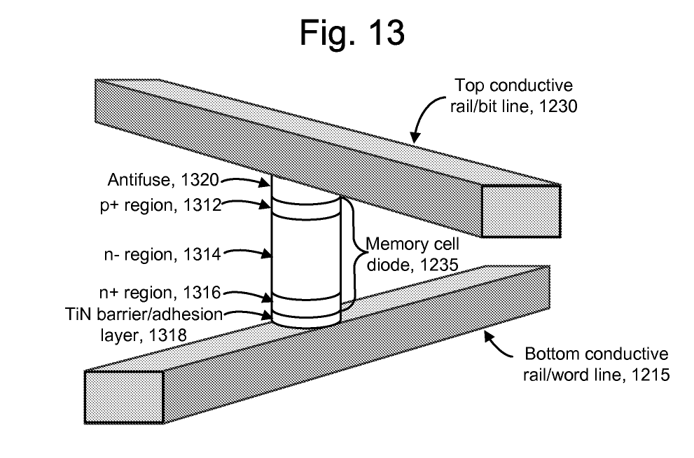

FIG. 13 depicts a memory cell in a 3-D memory device. U.S. Pat. No. 6,952,030, incorporated herein by reference, discloses an example configuration of the memory cell 1235. In this case, the memory cell includes a vertically oriented junction diode and a dielectric rupture antifuse interposed between top and bottom conductors. In particular, a vertically oriented junction diode 1235 includes a heavily doped semiconductor layer 1312 of a first conductivity type (e.g., p+ type), a layer 1314 which is undoped or lightly doped semiconductor material, and a heavily doped semiconductor layer 1316 of a second conductivity type (e.g., n+ type). The semiconductor material of diode 1235 can be, e.g., silicon, germanium, or an alloy of silicon and/or germanium. Diode 1235 and dielectric rupture antifuse 1320 are arranged in series between a bottom conductor/word line 1215 and a top conductor/bit line 1230, which may be formed of a metal such as tungsten. The conductors can be in the form of rails or other elongated members which extend parallel to one another in a given level and transverse to one another in alternating levels. A titanium nitride adhesion and barrier layer 1318 can also be provided between the diode 1235 and the bottom conductive rail 1215.

The diode 1235 can be a junction diode, which is a semiconductor device with the property of non-ohmic conduction, having two terminal electrodes, and made of semiconducting material which is p-type at one electrode and n-type at the other. Examples include p-n diodes and n-p diodes, which have p-type semiconductor material and n-type semiconductor material in contact, such as Zener diodes, and p-i-n diodes, in which intrinsic (undoped) semiconductor material is interposed between p-type semiconductor material and n-type semiconductor material.

In one possible approach, the heavily doped n-type silicon layer 1316 is provided and doped in situ, followed by the layer 1314 of intrinsic or lightly doped silicon. Silicon regions 1316 and 1314 can be amorphous as deposited, and crystallized later to polycrystalline silicon, also referred to as polysilicon. Note that the p+ region 1312 can be formed after the silicon is patterned and etched into pillars. For instance, ion implantation of a p-type dopant, for example boron or BF₂, can be used to form a shallow junction. For simplicity, formation of a p-i-n diode having an n-region at the bottom and a p-region at the top, formed of silicon, has been described. In alternate embodiments, the polarity of the diode could be reversed, or the semiconductor may be germanium, a silicon-germanium alloy, or some other material.

In the initial state of the memory cell, the diode 1235 acts as an open (non-conductive) circuit when a read voltage is applied between the top conductor 1230 and the bottom conductor 1215. The antifuse 1320 impedes current flow, and in most embodiments the polycrystalline semiconductor material of diode 1235 is formed in a relatively high-resistivity state. Application of a programming voltage between the top conductor 1230 and the bottom conductor 1215 causes dielectric breakdown of the antifuse material, permanently forming a conductive path through the antifuse 1320. The semiconductor material of diode 1235 is altered as well, changing it to a lower-resistivity state. After programming, a readily detectable current flows between the top conductor 1230 and the bottom conductor 1215 upon application of a read voltage. In this way a programmed cell can be distinguished from an unprogrammed cell. Further, the cell is binary. For example, a logical one value can be assigned when no current flows, and a logical zero value can be assigned when current flows. Various other memory cell configurations are possible.

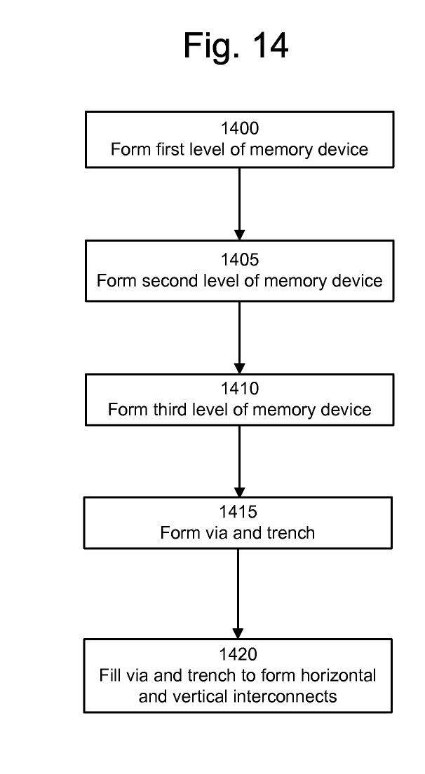

FIG. 14 depicts a process for forming a 3-D integrated circuit. In the example process, three levels are formed. However, the process can be adapted to form any number of levels. Steps 1400, 1405 and 1410 include forming first, second and third levels of the memory device, one after another. For each level, various steps for forming the memory cells, word lines and bit lines can be performed. Step 1415 includes forming an overlapping via and trench using a dual damascene process with amorphous carbon hard mask. Step 1420 includes filling the via and trench with conductive material.

In one embodiment, a method for fabricating a semiconductor device includes forming a pattern in at least one layer in a semiconductor structure using a photolithographic process, where the pattern includes at least one void in the at least one layer. The method further includes depositing an additional layer on top-facing surfaces of the at least one layer, and in the at least one void, where the additional layer coats walls of the at least one void. The method further includes applying a protective coat on top-facing surfaces of the additional layer, and in the at least one void. The method further includes performing chemical-mechanical polishing using a slurry to remove portions of the protective coat which are on the top-facing surfaces of the additional layer and to remove portions of the additional layer which are on the top-facing surfaces of the at least one layer, where a portion of the protective coat which is in the at least one void traps portions of the slurry, limiting an extent to which the slurry can enter the at least one void. The method further includes performing a cleaning process to remove the portion of the protective coat which is in the at least one void and the portions of the slurry which are trapped by the portion of the protective coat which is in the at least one void.

In another embodiment, a method for fabricating a semiconductor device includes using a photolithographic process, forming a pattern through multiple layers of a semiconductor structure of a 3-D monolithic memory device, where each of the multiple layers includes memory cells, and the pattern includes at least one void which extends in the multiple layers. The method further includes depositing an additional layer on top-facing surfaces of the at least one layer, and in the at least one void, where the additional layer coats walls of the at least one void. The method further includes applying a protective coat on top-facing surfaces of the additional layer, and in the at least one void. The method further includes performing chemical-mechanical polishing using a slurry to remove portions of the protective coat which are on the top-facing surfaces of the additional layer and to remove portions of the additional layer which are on the top-facing surfaces of the at least one layer, where a portion of the protective coat which is in the at least one void traps portions of the slurry, limiting an extent to which the slurry can enter the at least one void. The method further includes performing a cleaning process to remove the portion of the protective coat which is in the at least one void and the portions of the slurry which are trapped by the portion of the protective coat which is in the at least one void.

In another embodiment, a method for fabricating a semiconductor device includes performing chemical-mechanical polishing using a slurry on a semiconductor structure which includes a protective coat formed on a metal layer. The protective coat includes a portion in a void of the semiconductor structure, and the metal layer includes a portion in the void, where the portion of the protective coat in the void traps portions of the slurry. The method further includes performing a cleaning process to remove the portion of the protective coat which is in the void and the portions of the slurry which are trapped by the portion of the protective coat which is in the void.

The foregoing detailed description has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application, to thereby enable others skilled in the art to best utilize the technology in various embodiments and with various modifications as are suited to the particular use contemplated. It is intended that the scope of the technology be defined by the claims appended hereto.

What is claimed is:

1. A method for fabricating a semiconductor device, comprising:
forming a pattern in at least one layer in a semiconductor structure using a photolithographic process, the pattern includes at least one void in the at least one layer;
depositing an additional layer on top-facing surfaces of the at least one layer, and in the at least one void, the additional layer coats walls of the at least one void;
applying a protective coat on top-facing surfaces of the additional layer, and in the at least one void;
performing chemical-mechanical polishing using a slurry to remove portions of the protective coat which are on the top-facing surfaces of the additional layer and to remove portions of the additional layer which are on the top-facing surfaces of the at least one layer, where a portion of the protective coat which is in the at least one void traps portions of the slurry, limiting an extent to which the slurry can enter the at least one void; and
performing a cleaning process to remove the portion of the protective coat which is in the at least one void and the portions of the slurry which are trapped by the portion of the protective coat which is in the at least one void.

2. The method of claim 1, further comprising:
using the at least one void as an alignment mark.

3. The method of claim 1, wherein:
a top of the at least one void has a cross-sectional area of about 100×200 nm to about 200×400 nm; and
a depth of the at least one void is at least about 800 nm.

4. The method of claim 1, wherein:
the protective coat is an organic layer.

5. The method of claim 1, wherein:
the protective coat is spin-on carbon.

6. The method of claim 1, wherein:
the protective coat is an ashable material.

7. The method of claim 1, wherein:
the protective coat is amorphous carbon.

8. The method of claim 1, wherein:
the protective coat is SiN.

9. The method of claim 1, wherein:
the protective coat is photoresist.

10. The method of claim 9, further comprising:
baking the semiconductor structure after the applying the protective coat and before the performing the chemical-mechanical polishing, to cure the photoresist.

11. The method of claim 1, wherein:
the at least one void extends through multiple layers of a 3-D monolithic memory device, each of the multiple layers includes memory cells.

12. The method of claim 1, wherein the chemical-mechanical polishing reveals the at least one layer, and the method further comprises:
filling the at least one void with a metal using chemical vapor deposition; and
sputtering a metal on the at least one layer and a top-facing surface of the metal which fills in the at least one void.

13. The method of claim 1, wherein:
the additional layer is a metal layer.

14. A method for fabricating a semiconductor device, comprising:
using a photolithographic process, forming a pattern through multiple layers of a semiconductor structure of a 3-D monolithic memory device, each of the multiple layers includes memory cells, the pattern includes at least one void which extends in the multiple layers;
depositing an additional layer on top-facing surfaces of the at least one layer, and in the at least one void, the additional layer coats walls of the at least one void;
applying a protective coat on top-facing surfaces of the additional layer, and in the at least one void;
performing chemical-mechanical polishing using a slurry to remove portions of the protective coat which are on the top-facing surfaces of the additional layer and to remove portions of the additional layer which are on the top-facing surfaces of the at least one layer, where a portion of the protective coat which is in the at least one void traps portions of the slurry, limiting an extent to which the slurry can enter the at least one void; and
performing a cleaning process to remove the portion of the protective coat which is in the at least one void and the portions of the slurry which are trapped by the portion of the protective coat which is in the at least one void.

15. The method of claim 14, wherein:
the protective coat is an organic layer.

16. The method of claim 14, further comprising:
using the at least one void as an alignment mark.

17. The method of claim 14, wherein:
a top of the at least one void has a cross-sectional area of about 100×200 nm to about 200×400 nm; and
a depth of the at least one void is at least about 800 nm.

18. The method of claim 14, wherein the chemical-mechanical polishing reveals the at least one layer, and the method further comprises:
filling the at least one void with a metal using chemical vapor deposition; and
sputtering a metal on the at least one layer and a top-facing surface of the metal which fills in the at least one void.

19. A method for fabricating a semiconductor device, comprising:
performing chemical-mechanical polishing using a slurry on a semiconductor structure which includes a protective coat formed on a metal layer, the protective coat includes a portion in a void of the semiconductor structure, and the metal layer includes a portion in the void, where the portion of the protective coat in the void traps portions of the slurry; and
performing a cleaning process to remove the portion of the protective coat which is in the void and the portions of the slurry which are trapped by the portion of the protective coat which is in the void.

20. The method of claim 19, wherein:
the protective coat is an organic layer.
